(19) United States
(12) Patent Application Publication
(10) Pub. No.: US 2013/0200509 A1
(43) Pub. Date: Aug. 8, 2013

(54) SEMICONDUCTOR PACKAGE

(71) Applicant: SAMSUNG ELECTRONICS CO., LTD., Suwon-si (KR)

(72) Inventor: Yong-Hoon KIM, Suwon-si (KR)

(73) Assignee: SAMSUNG ELECTRONICS CO., LTD., Suwon-si (KR)

(21) Appl. No.: 13/660,317

(22) Filed: Oct. 25, 2012

(30) Foreign Application Priority Data
Feb. 2, 2012 (KR) 10-2012-0010865

(51) Int. Cl. H01L 23/488

(52) U.S. Cl. 257/692; 257/E23.023

(57) ABSTRACT

A semiconductor package includes a substrate including a mounting surface having a plurality of ground pads, a semiconductor chip disposed on the mounting surface, a conductive connection part connected to at least one of the plurality of ground pads and having a greater width at a center than at an end, a molding member exposing a top surface of the conductive connection part while wrapping the mounting surface, the conductive connection part and the semiconductor chip, and a heat slug disposed on the molding member and connected to the top surface of the conductive connection part.

### CROSS-REFERENCE TO RELATED APPLICATIONS

This application claims priority under 35 U.S.C. §119 from Korean Patent Application No. 10-2012-0010865 filed on Feb. 2, 2012 in the Korean Intellectual Property Office, and all the benefits accruing therefrom under 35 U.S.C. 119, the contents of which in its entirety are herein incorporated by reference.

### BACKGROUND

1. Field

The present general inventive concept relates to a semiconductor package.

2. Description of the Related Art

According to demands on high-performance electronic devices, a size of a semiconductor chip increases and a semiconductor package also increases. On the other hand, according to the trend toward slimness of an electronic device, a thickness of a semiconductor package is reduced. In order to achieve a high-performance electronic device, multiple semiconductors are used in a semiconductor package. As the result, several problems, such as heat generation, frequency interference, and so on, occur. Accordingly, effective heat emission of a semiconductor package and improved electromagnetic interference (EMI) and electrostatic discharge (ESD) are required.

Along with development of high-speed electronic devices and increased operation frequency, a semiconductor package may undergo problems of power integrity (PI), signal integrity (SI), or electromagnetic interference (EMI). In particular, a portable device, such as a cellular phone, has a severe problem of EMI, which lowers reception sensitivity. In addition, as the power used is increased, it is necessary to effectively emit heat generated from the semiconductor package.

### SUMMARY

The present general inventive concept provides a semiconductor package having improved characteristics in view of heat emission, electromagnetic interference (EMI) and electrostatic discharge (ESD) by grounding a heat slug on a ground pad using a conductive connection part.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a semiconductor package including a substrate including a mounting surface having a plurality of ground pads, a semiconductor chip disposed on the mounting surface, a conductive connection part connected to at least one of the plurality of ground pads and having a center portion with a width wider than that at an end, a molding member wrapping the mounting surface, the conductive connection part and the semiconductor chip and exposing a top surface of the conductive connection part, and a heat slug disposed on the molding member and connected to the top surface of the conductive connection part.

The foregoing and/or other features and utilities of the present general inventive concept may also be achieved by providing a semiconductor package including a substrate including a mounting surface having a plurality of ground pads, a lower semiconductor chip disposed on the mounting surface, an upper semiconductor chip disposed on the lower semiconductor chip, a conductive connection part connected to at least one of the plurality of ground pads, a molding member wrapping the mounting surface, the solder ball, the upper semiconductor chip and the lower semiconductor chip and exposing a top surface of the solder ball, and a heat slug disposed on the molding member and connected to the top surface of the solder ball.

The foregoing and/or other features and utilities of the present general inventive concept may also be achieved by providing a semiconductor package including a substrate formed with one or more ground pads at a first position of the substrate, a semiconductor chip disposed on the substrate at a second position of the substrate, a conductive connection part formed on the corresponding ground pad and having a width variable according to a distance from the corresponding ground pad, a molding member formed between the semiconductor chip and the conductive connection part, and a heat transferring unit connected to the conductive connection part and disposed to cover the molding member and at least a portion of the semiconductor chip.

The heat transferring unit may include a heat slug, and the conductive connection part may be extended from the corresponding ground pad in a direction having an angle with the substrate to contact the heat slug.

The conductive connection part may be spaced apart from the semiconductor by a distance longer than the width of the conductive connection part.

The conductive connection part may have a bottom area, the ground pad may have a surface area, and the surface area may be larger than the bottom area.

The semiconductor package may further include a supporter disposed on a third position of the substrate between the semiconductor chip and the conductive connection part to support the heat transferring unit with respect to the substrate.

The semiconductor package may further include a film disposed beneath the heat transferring unit to maintain a distance from the substrate.

The semiconductor package may further include a second semiconductor chip disposed between the semiconductor chip and the heat transferring unit to be electrically connected to either one of the semiconductor chip and the substrate.

The foregoing and/or other features and utilities of the present general inventive concept may also be achieved by providing an electronic apparatus having a communication interface to communicate with an external device to transmit or receive data, a storage unit to store data, and a functional unit to process the data of the external device or the storage unit, and the storage unit may include the above-described semiconductor package.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a cross-sectional view illustrating a semiconductor package according to an embodiment of the present general inventive concept;

FIG. 2 is a plan view illustrating a substrate used in the semiconductor package of FIG. 1;

FIG. 3 is a plan view illustrating a portion of the semiconductor package of FIG. 1;

FIG. 4 is a cross-sectional view taken along the line AA of FIG. 3;

FIGS. 5A and 5B are enlarged views of a portion I of FIG. 4;

FIG. 6A is a view illustrating a semiconductor package and FIG. 6B is a cross-sectional view taken along the line BB of FIG. 6A according to an embodiment of the present general inventive concept;

FIG. 7 is a view illustrating a semiconductor package according to an embodiment of the present general inventive concept;

FIG. 8 is a cross-sectional view illustrating a semiconductor package according to an embodiment of the present general inventive concept;

FIG. 9 is a cross-sectional view illustrating a semiconductor package according to an embodiment of the present general inventive concept;

FIG. 10 is a cross-sectional view illustrating a semiconductor package according to an embodiment of the present general inventive concept;

FIG. 11 is a cross-sectional view illustrating a portion of the semiconductor package of FIG. 10 according to an embodiment of the present general inventive concept;

FIGS. 12 and 13 are views illustrating portions of the semiconductor package of FIG. 10;

FIGS. 14 and 15 are cross-sectional views illustrating a semiconductor package according to an embodiment of the present general inventive concept;

FIGS. 16A and 16B are cross-sectional views illustrating a semiconductor package according to an embodiment of the present general inventive concept;

FIG. 17 illustrates a package-on-package structure using a semiconductor package according to an embodiment of the present general inventive concept;

FIGS. 18A and 18B are views illustrating an electronic device having one or more semiconductor packages according to an embodiment of the present general inventive concept;

FIG. 19 is a flowchart illustrating a manufacturing method of a semiconductor package according to an embodiment of the present general inventive concept; and

FIG. 20 is a flowchart illustrating a method of manufacturing one or more semiconductor packages according to an embodiment of the present general inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present invention.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

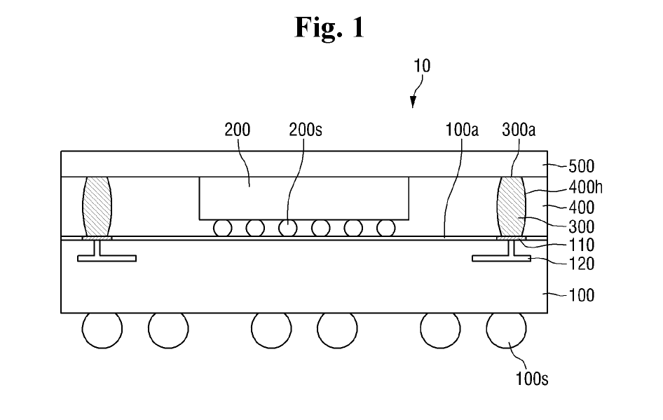

Hereinafter, a semiconductor package according to an embodiment of the present general inventive concept will be described with reference to FIGS. 1 to 7.

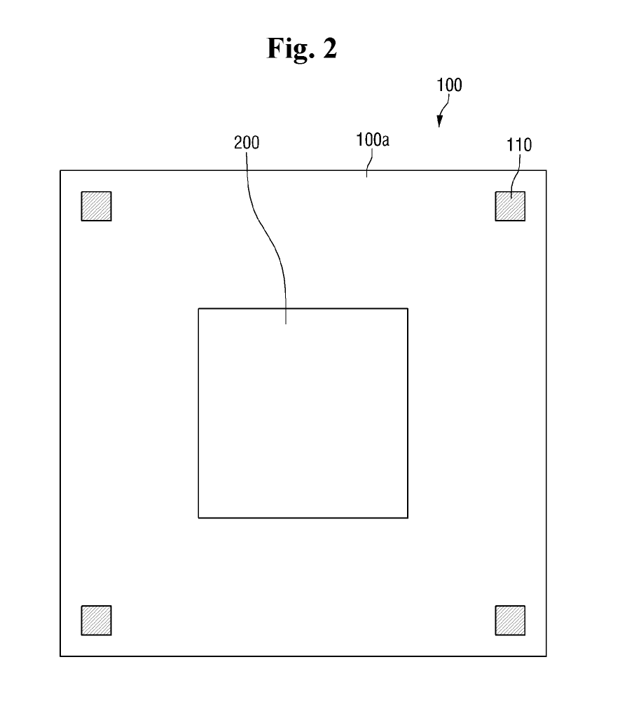

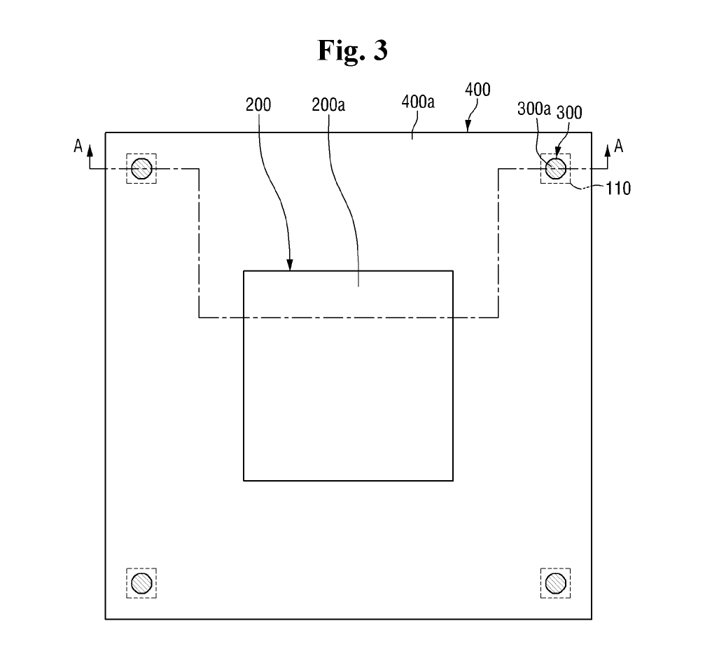

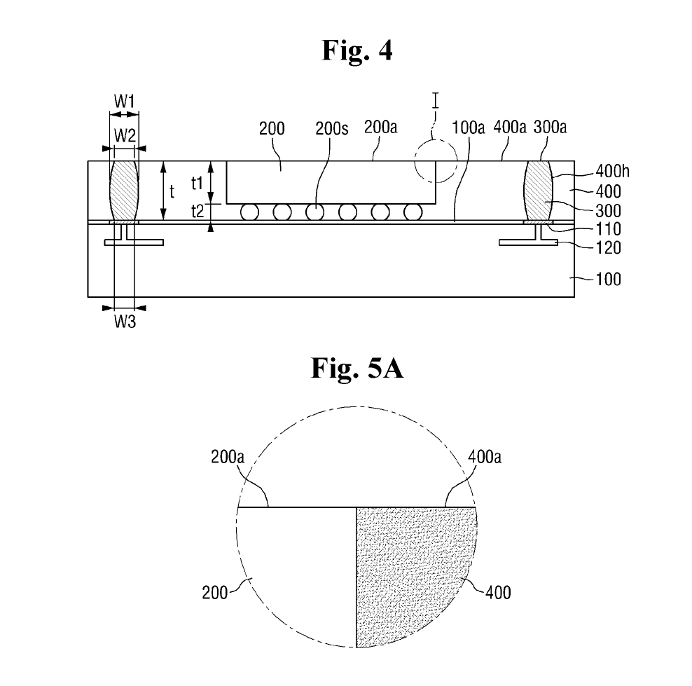

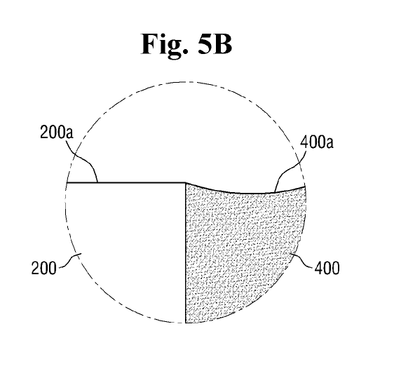

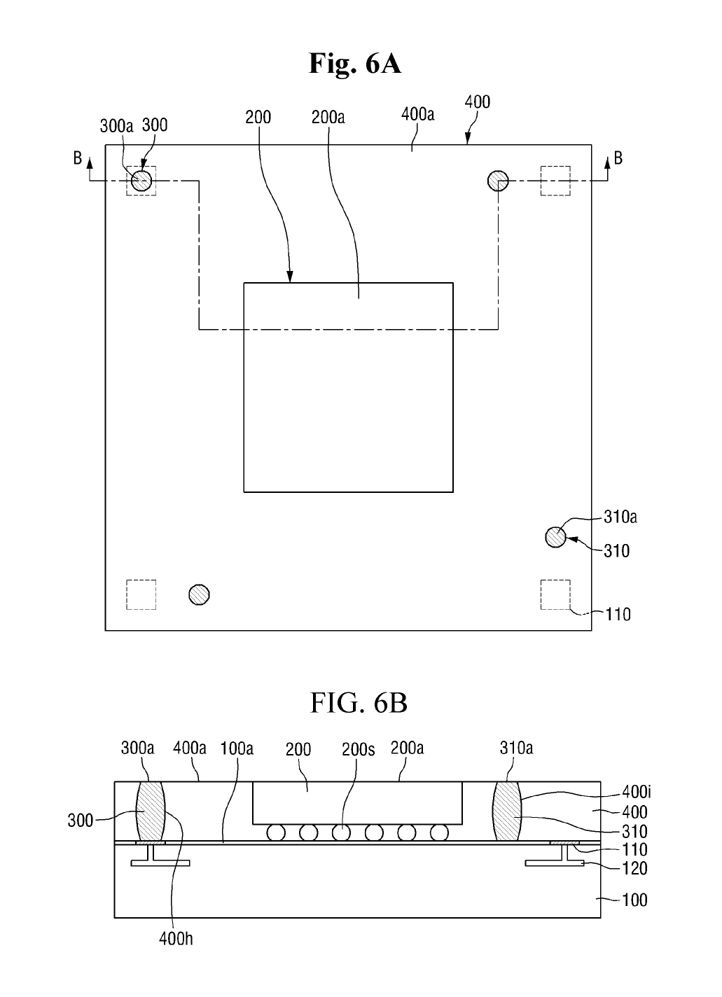

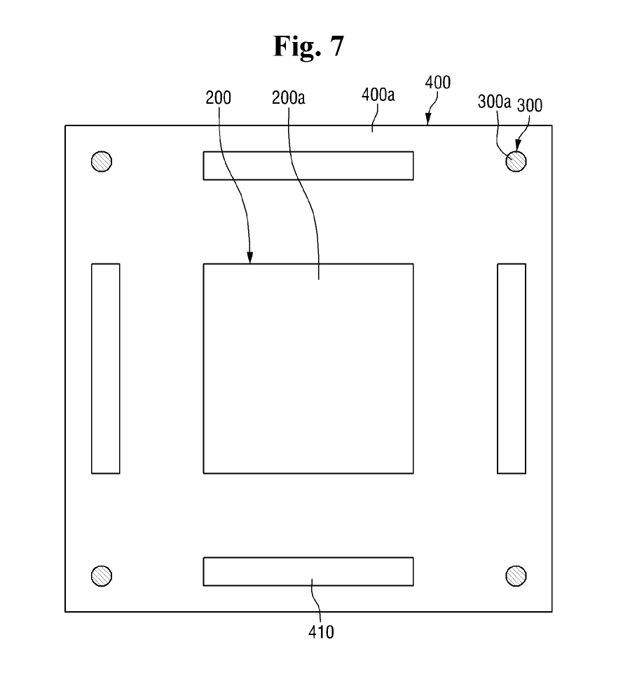

FIG. 1 is a cross-sectional view illustrating a semiconductor package 10 according to an embodiment of the present general inventive concept, FIG. 2 is a plan view illustrating an example of a substrate used in the semiconductor package 10 of FIG. 1, FIG. 3 is a plan view illustrating the semiconductor package of FIG. 1 from which a heat slug is excluded, FIG. 4 is a cross-sectional view taken along the line AA of FIG. 3, FIGS. 5A and 5B are enlarged views of a portion I of FIG. 4, FIG. 6A is a plan view illustrating a portion of the semiconductor package 10 of FIG. 1 from which a heat discharging or transferring unit (or heat slug) is excluded, and FIG. 6B is a cross-sectional view taken along the line BB of FIG. 6A, and FIG. 7 is a plan view illustrating a portion of the semiconductor package 10 of FIG. 1 from which a heat discharging or transmitting unit (or heat slug is excluded.

Referring to FIG. 1, the semiconductor package 10 includes a substrate 100, a semiconductor chip 200, conductive connection parts 300, a molding member 400 and a heat discharging or transferring unit (hereinafter, referred to as a heat slug) 500. The substrate 100 includes a mounting surface 100a having a plurality of ground pads 110. The semiconductor chip 200 is disposed on the mounting surface 100a and is electrically connected to the substrate 100. The conductive connection parts 300 are connected to at least one of the plurality of ground pads 110 formed on the mounting surface 100a. The molding member 400 exposes top surfaces 300a of the conductive connection parts 300 while wrapping the mounting surface 100a, the conductive connection parts 300 and the semiconductor chip 200. The heat slug 500 is disposed on the molding member 400 and is connected to the top surfaces 300a of the conductive connection parts 300a.

The substrate 100 may be a board for a package, for example, a printing circuit board (PCB) or a ceramic substrate. At least one external terminal 100s, such as solder balls, which electrically connect the semiconductor package 10 to an external device, may be attached to a bottom surface of the substrate 100, that is, a surface corresponding to the mounting surface 100a on which the semiconductor chip 200 is mounted. The plurality of ground pads 110 formed on the mounting surface 100a are connected to ground lines 120 in the substrate 100.

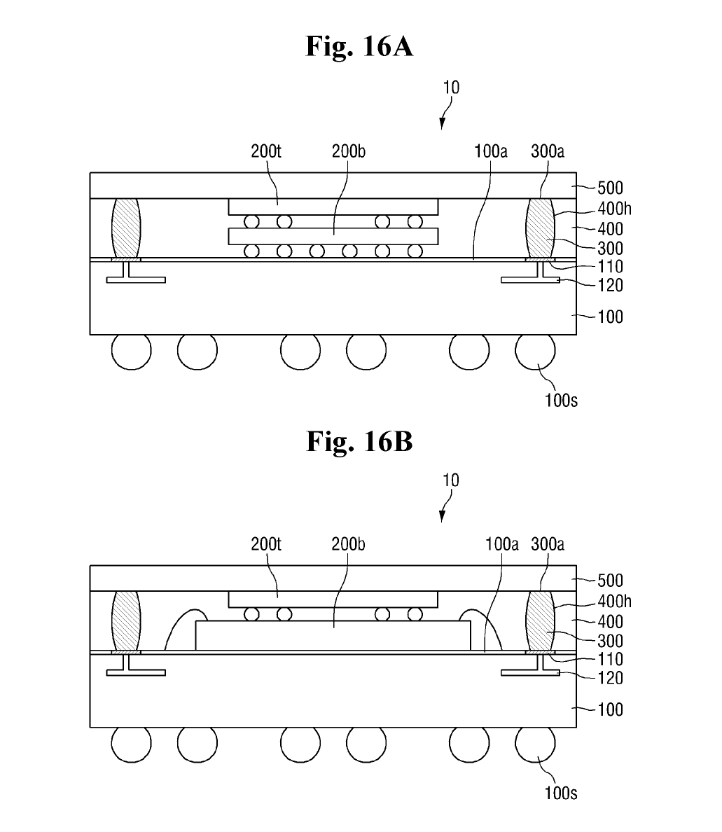

The semiconductor chip 200 may be, for example, a memory chip, a logic chip, or the like. The semiconductor chip 200 may include a plurality of semiconductor chips, which will later be described with reference to FIGS. 16A and 16B. The semiconductor chip 200 may be electrically connected to the circuit board of the substrate 100 by a solder ball 200s. The semiconductor chip 200 may be mounted in form of, for example, a flip chip. The solder ball 200s may be formed on a surface where semiconductor device circuits are formed. Alternatively, the solder ball 200s may be connected to a through hole via (TSV) extending through the semiconductor chip 200.

In the semiconductor package 10 according to an embodiment of the present general inventive concept, it is possible that a conductive wire can be usable to connect the semiconductor chip 200 to the substrate 100 instead of the solder balls 220s.

Each of the conductive connection parts 300 may have a shape, for example, a shape of a pillar having a bulging center. The conductive connection part 300 has a larger width at its center than at its end. A width of the end of the conductive connection part 300 connected to the heat slug 500 or the ground pad 110 may be smaller than a width of the center of the conductive connection part 300 in a lengthwise direction. The conductive connection parts 300 may be, for example, solder balls. Shapes of the conductive connection parts 300 will be described with reference to FIG. 4.

The molding member 400 may include a hole 400h to accommodate the conductive connection part 300. The molding member 400 may completely fill a space between the semiconductor chip 200 and the mounting surface 100a. The molding member 400 may completely wrap the semiconductor chip 200 and side surfaces of the conductive connection part 300. The molding member 400 may include, for example, epoxy molding compound (EMC). The molding member 400 may be formed by, for example, a molded underfill (MUF) method.

The heat slug 500 may be shaped of, for example, a planar panel or a thin foil. The heat slug 500 is made of a heat conductive material or an electro-conductive material. The heat slug 500 may include, for example, a metal panel or a metal foil. An example of the heat slug 500 may include a copper panel, an aluminum panel, a copper foil, an aluminum foil, and combinations thereof. The heat slug 500 and the conductive connection parts 300 may be electrically connected to each other by forming a connection part using wetting through heat treatment, for example. The heat slug 500 and the semiconductor chip 200, or the heat slug 500 and the molding member 400, may be attached to each other using an adhesive. However, the present general inventive concept is not limited thereto. It is possible that an attaching element or material can be used or formed to couple the heat slug 500 and one of the semiconductor chip 200 and the molding member 400.

In the semiconductor package 10 according to an embodiment of the present general inventive concept, the heat slug 500 and the substrate 100 are connected to each other by means of the conductive connection parts 300. The heat slug 500 is connected to the ground lines 120 disposed in the substrate 100 through the conductive connection parts 300. Since the heat slug 500 is made of a material having excellent heat conductivity and electric conductivity, it can effectively emit, transmit or discharge the heat generated from the semiconductor chip 200. In addition, the heat slug 500 can block external EMI to allow the semiconductor chip 200 to accurately operate and can protect the semiconductor chip 200 from electrostatic shocks. In the embodiment of the present general inventive concept, the molding member 400 is configured to wrap the side surfaces of the conductive connection parts 300, thereby securing structural stability of the semiconductor package 10. It is possible that a solder ball can be usable as the conductive connection part 300. In this case, a manufacturing cost of the semiconductor package 10 may not be increased due to a low manufacturing cost of the solder ball, and the heat slug 500 can be effectively grounded to the substrate 100 because of excellent electric conductivity of the solder ball.

Referring to FIG. 2, a plurality of ground pads 110 are formed on the mounting surface 100a. Although FIG. 2 shows that the ground pads 110 are formed around corners (corner portions) of the substrate 100, it is possible that the ground pads 110 may also be formed around edges (side portions) of the mounting surface 100a. However, the present general inventive concept is not limited thereto. The plurality of ground pads 110 are connected to ground lines among multiple wirings formed in the substrate 100. Each of the ground pads 110 may have, for example, a rectangular shape. However, the present general inventive concept is not limited thereto. The ground pads 110 positioned around the corners of the substrate 100 may be formed by assembled multiple pads. The semiconductor chip 200 may be positioned, for example, around a center portion of the mounting surface 100a. The semiconductor chip 200 may have, for example, a square shape. Alternatively, the semiconductor chip 200 may also have a rectangular shape. When a connection pad of the semiconductor chip 200 is used to connect the semiconductor chip 200 to the substrate 100 through, for example, a silicon through hole via (TSV), a silicon through-electrode may be formed on a top surface of the semiconductor chip 200 to correspond to the connection pad.

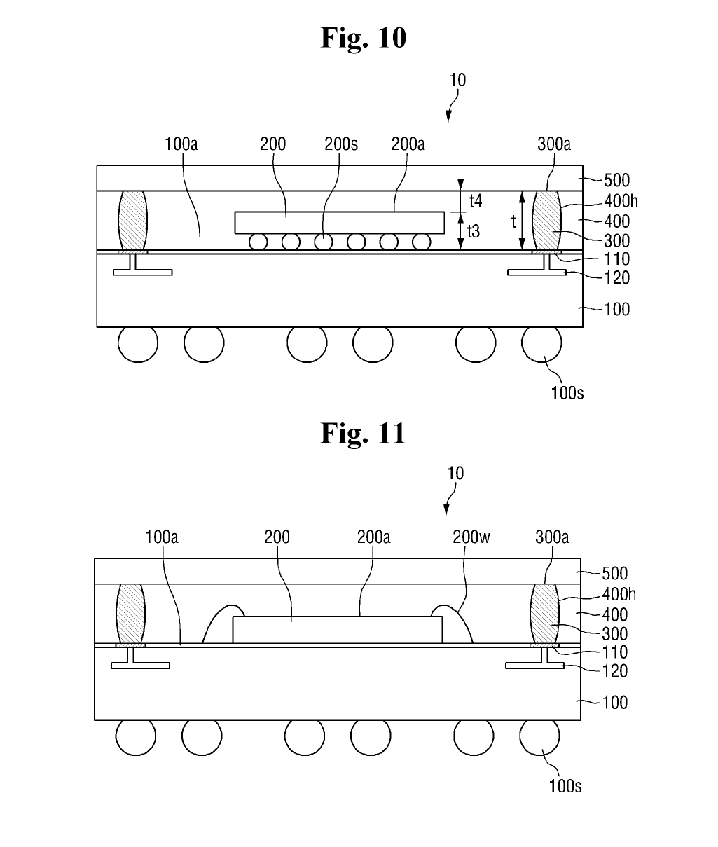

Referring to FIG. 3, a top surface 200a of the semiconductor chip 200 and a top surface 300a of the conductive connection parts 300 are exposed from a top surface 400a of the molding member 400. In the illustrated embodiment, the molding member 400 exposes one surface of the semiconductor chip 200. That is, the side surfaces of the semiconductor chip 200 are completely wrapped by the molding member 400. However, the top surface 200a of the semiconductor chip 200 is exposed to the outside of the molding member 400. A case where the top surface 200a of the semiconductor chip 200 is not exposed will be described with reference to FIGS. 10 to 13. For example, the molding member 400 fixes the semiconductor chip 200 and the conductive connection parts 300 so as not to be moved.

Referring to FIGS. 1, 2, and 3, the conductive connection parts 300 are disposed on the ground pads 110 formed around the corners of the mounting surface. The conductive connection parts 300 have only to be connected to at least one of the ground pads 110. However, for brevity of explanation, the conductive connection parts 300 are disposed on all of the ground pads 110. For example, the conductive connection parts 300 may be connected to the ground pads 110 by heat treatment. The molding member 400 may cover the top surface 300a of the conductive connection parts 300 and may expose the top surface 300a of the conductive connection parts 300 by, for example, grinding. A cross-sectional shape of the top surface 300a of the conductive connection parts 300 may be, a circular shape, but aspects of the present invention are not limited thereto.

Referring to FIGS. 1 through 4, the side surfaces of the conductive connection parts 300 are wrapped by the molding member 400. That is to say, the molding member 400 may include the hole 400h to accommodate each of the conductive connection parts 300. The hole 400h have the same shape with the side surfaces of the conductive connection part 300. The conductive connection part 300 may be shaped of, for example, a pillar having a bulging center and narrow ends. For example, the bulging pillar shape may be extended in a lengthwise direction. In other words, the conductive connection part 300 may be shaped of, for example, a jar. On a cross-sectional view, when a portion of the conductive connection part 300 connected to the ground pads 110 may have a width w3, a portion w of the conductive connection part 300 exposed to the outside of the molding member 400 may have a width w2, and a center portion of the bulging part positioned in the center of the conductive connection parts 300 may have a width w1 in a lengthwise direction, the width w1 is greater than the widths w2 and w3. That is, the cross-sectional width of the conductive connection part 300 may be largest at the portion having the width w1. The width w3 of the portion where the conductive connection part 300 is connected to the ground pads 110 and the width w2 of the portion where the conductive connection part 300 is exposed to the outside of the molding member 400 may be determined according to a design preference or manufacturing process. The same dimensional relationship of widths w1, w2 and w3 may be applied to the hole 400h to accommodate the conductive connection part 300. When the hole 400h of the molding member 400 has a shape to be exactly fitted on the side surfaces of the conductive connection part 300, the side surfaces of the conductive connection parts 300 may come into direct contact with the molding member 400. In the semiconductor package 10 according to an embodiment of the present general inventive concept, when the conductive connection part 300 is a solder ball shaped of a pillar having a bulging center, the side surfaces of the solder ball may come into direct contact with the molding member 400. In addition, one end of the solder ball, which is not connected to the ground pad 110, is exposed to the top surface 400a of the molding member 400.

Referring to FIG. 4, the semiconductor chip 200 is connected to the substrate 100 by solder balls 200s. The conductive connection parts 300 are connected to the ground pads 110. It is assumed that the solder ball 200s and the conductive connection parts 300 are disposed on the planar mounting surface having the same level with the solder ball 200s and the conductive connection parts 300. When the conductive connection part 300 has a height t, the solder ball 200s has a height t2, and the semiconductor chip 200 has a thickness t1, a sum of the height t1 and t2 may be equal to the height t. In addition, a sum of the thickness t1 of the semiconductor chip 200 mounted on the substrate 100 and the height t2 of the solder ball 200s may be equal to a thickness of the molding member 400. Therefore, the thickness of the molding member 400 wrapping the conductive connection part 300 may be equal to the height t of the conductive connection part 300. Here, the term “equal height” may be used to mean two or more heights compared are completely equal to each other and to encompass a height difference generated due to a processing margin, which is provided only for explaining a semiconductor package according to an embodiment of the present general inventive concept. However, the present general inventive concept is not limited thereto. In addition, the term “equal height” may be used to encompass a height difference between the ground pads 110 connected to the conductive connection parts 300 and the mounting surface 100a connected to the solder ball 200s.

Referring to FIG. 5A, the top surface 200a of the semiconductor chip 200 and the top surface 400a of the molding member 400 may be coplanar. When the top surface 200a of the semiconductor chip 200 and the top surface 400a of the molding member 400 are not formed on significantly different planes or the top surface 200a of the semiconductor chip 200 and the top surface 400a of the molding member 400 do not have significantly different heights, the top surface 200a of the semiconductor chip 200 and the top surface 400a of the molding member 400 may be formed on a coplanar surface. For example, different portions of the top surfaces may be planarized through grinding to be coplanar. Referring to FIG. 5B, the top surface 400a of the molding member 400 may be curved. Although FIG. 5B shows that the top surface 400a of the molding member 400 is concavely curved, it is possible that the top surface 400 of the molding member 400 can be convexly curved. For example, when a portion between the semiconductor chip 200 and the molding member 400 is subjected to grinding, the top surface 400a of the molding member 400 may be formed to have a curved shape.

Referring to FIGS. 1 and 6A, the semiconductor package 10 according to an embodiment of the present general inventive concept may further include a supporter 310. The supporter 310 is wrapped by the molding member 400. The supporter 310 may not be disposed on a portion of the mounting surface 100a corresponding to the ground pads 110. The supporter 310 may connect the mounting surface 100a of the substrate with the heat slug 500. The supporter 310 may be attached to the heat slug 500 by, for example, an adhesive that is not electrically connected. The top surface 200a of the semiconductor chip 200, the top surface 300a of the conductive connection part 300 and the top surface 310a of the supporter 310 are exposed from the top surface 400a of the molding member 400. For example, the molding member 400 may fix the semiconductor chip 200, the conductive connection parts 300 and the supporter 310 so as not to be moved with respect to the substrate 100.

The conductive connection part 300 is disposed on the ground pad 110 formed around a corner portion of the mounting surface 110a. Although FIG. 6A shows that one conductive connection part 300 is connected to the ground pad 110, it is illustrated only for explanation. However, the present general inventive concept is not limited thereto. The supporter 310 is disposed at a portion of the mounting surface 100a, which is not a portion where the ground pad 110 is formed, that is, which is a portion not overlapping with the ground pad 110 in a plan view. Although the supporter 310 is illustrated to be disposed around the ground pad 110, the present general inventive concept is not limited thereto. The supporter 310 is connected to the substrate 100 to then be fixed on the substrate 100. The supporter 310 facilitates fixing of the heat slug 500 used in the semiconductor package 10 so as not to be moved with respect to the substrate 100. That is, in order to more securely fix the heat slug 500 fixed on the substrate 100 by the conductive connection parts 300 and the molding member 400, the supporter 310 may be additionally used.

The supporter 310 may be made of, for example, a conductive material. An example of the supporter 310 may be a solder ball. However, since the supporter 310 is not used for the purpose of thermally or electrically connecting the heat slug 500 with the ground pad 110, it may be made of an insulating material. It is illustrated that the top surface 310a of the supporter 310 is circular, like the top surface 300a of the conductive connection part 300, but the present general inventive concept is not limited thereto.

Referring to FIGS. 1, 6A, and 6B, the conductive connection parts 300 disposed on the ground pads 110 and the supporter 310 disposed on the mounting surface 100a other than the ground pads 110 are wrapped by the molding member 400. Like the hole 400h accommodating the conductive connection part 300, a hole 400i to accommodate the supporter 310 in the molding member 400 may have the same shape with the side surfaces of the supporter 310. The supporter 310 may be shaped of, for example, a pillar having a bulging center, like the conductive connection part 300. In other words, the supporter 310 may be shaped of, for example, a jar, but the present general inventive concept is not limited thereto. For example, the supporter 310 may be formed after the mounting surface 100a, the semiconductor chip 200 and the conductive connection parts 300 are covered by the molding member 400. The supporter 310 may be formed by forming a hole exposing the mounting surface 100a in the molding member 400 by, for example, laser drilling and filling the hole. Here, a width of a portion where the supporter 310 meets the mounting surface 100a and a width of a portion exposed to the outside of the molding member 400 may be equal to each other. In addition, the width of a portion where the supporter 310 meets the mounting surface 100a may be smaller than the width of a portion exposed to the outside of the molding member 400. In addition, a height of the supporter 310 may be equal to a sum of a thickness of the semiconductor chip 200 and a height of the solder ball 200s and may be equal to a thickness of the molding member 400.

Referring to FIGS. 1 and 7, the semiconductor package 10 according to an embodiment of the present general inventive concept may further include an adhesive film 410 formed on the top surface 400a of the molding member 400. The adhesive film 410 is disposed between the molding member 400 and the heat slug 500 of FIG. 1. The adhesive film 410 may connect the molding member 400 with the heat slug by attaching the top surface 400a of the molding member 400 to the heat slug 500. The adhesive film 410 may be formed on a position of the surface 400a of the molding member 400 not overlapping a position of the semiconductor chip 200 and the conductive connection parts 300. However, the present general inventive concept is not limited thereto.

In an embodiment of the present general inventive concept, the adhesive film 410 may not be positioned on the top surface 200a of the semiconductor chip 200 and may not be positioned on the top surface 300a of the conductive connection part 300. In FIG. 7, the adhesive film 410 may be disposed around the top surface 200a of the semiconductor chip 200 and may be disposed between the top surfaces 300a of the conductive connection parts 300. However, the present general inventive concept is not limited thereto. In the illustrated embodiment of the present general inventive concept, a planar shape of the adhesive film 410 is a rectangle, but the present general inventive concept is not limited thereto. It is possible that the adhesive film 410 may have a polygonal shape or a circular shape. The adhesive film 410 tightly fixes the heat slug 500 and the top surface 400a of the molding member 400 to prevent the heat slug from moving with respect to the molding member 400, thereby achieving structural stability of the semiconductor package 10.

However, a location of the adhesive film 410 may vary according to electrical properties of the adhesive film 410. For example, when the adhesive film 410 is an electrical conductive adhesive, it may be formed on the top surface 400a of the molding member 400 and/or the top surface 200a of the semiconductor chip 200. That is, the adhesive film 410 may be formed on any portion of the top surface 400a of the molding member 400, the top surface 200a of the semiconductor chip 200, or the top surface 300a of the conductive connection part 300, since the heat slug 500 of FIG. 1 and the ground pad 110 of FIG. 1 are electrically connected to each other. However, when the adhesive film 410 is a non-electrical conductive adhesive, at least one of the conductive connection parts 300 should not be covered by the adhesive film 410, since the at least one of the conductive connection parts 300 is to connect the heat slug 500 to the ground pad 110 to ground the heat slug 500.

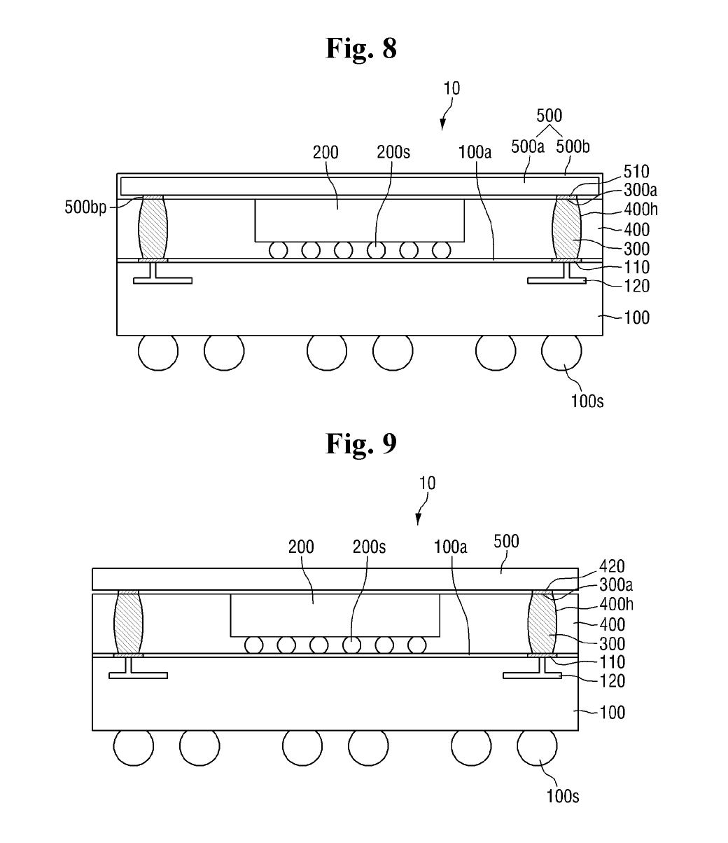

A semiconductor package according to an embodiment of the present general inventive concept will now be described with reference to FIG. 8. The semiconductor package 10 of FIG. 8 is substantially the same as the semiconductor package 10 illustrated in FIGS. 1 to 7, except for a configuration of a heat slug, and thus the same portions will not be repeatedly described or briefly described.

FIG. 8 is a cross-sectional view illustrating a semiconductor package 10 according to an embodiment of the present general inventive concept.

Referring to FIGS. 1 and 8, the heat slug 500 includes a center part 500a and an edge part 500b wrapping the center part 500a or disposed on the center part 500a. The center part 500a may be made of, for example, a metallic material having good thermal conductivity and electric conductivity, such as copper, (Cu), aluminum (Al) or a combination thereof. The edge part 500b may be made of, for example, a metallic material that is strong against corrosion, such as a metal that is strong to an oxidation reaction. For example, the edge part 500b may be made of nickel (Ni), but not limited thereto.

The edge part 500b may include a pattern 500bp exposing the center part 500a. The pattern 500bp of the edge part 500bp is formed at a location corresponding to the top surface 300a of the conductive connection part 300. The heat treatment may make it difficult for a metal used for the edge part 500b to be attached to the conductive connection parts 300 by wetting. Therefore, in order to connect the conductive connection parts 300 and the heat slug 500 to a connection part 510 having good electric conductivity, it is necessary to form the pattern 500bp exposing the center part 500a at the edge part 500bp through the heat treatment. The semiconductor package 10 according to an embodiment of the present general inventive concept illustrates the center part 500a made of, for example, copper, and the conductive connection parts 300 made of, for example, solder balls. The solder ball (for example, made of SnAgCu) is well wetted to copper, so that it can be efficiently attached thereto. To this end, the connection part 510 is generated (formed) between the center part 500a and the conductive connection part 300, and the generated connection part 510 has good electric conductivity. Therefore, the conductive connection part 300 is attached and connected to the heat slug 500 and electrically connects the heat slug 500 to the ground pad 110.

A semiconductor package according to an embodiment of the present general inventive concept will now be described with reference to FIG. 9. The semiconductor package of FIG. 9 is substantially the same as the semiconductor package 10 illustrated in FIGS. 1 to 7, except a conductive adhesive provided to connect a heat slug and a conductive connection part, and thus the same portions will not be repeatedly described or briefly described.

FIG. 9 is a cross-sectional view illustrating a semiconductor package 10 according to an embodiment of the present general inventive concept.

Referring to FIGS. 1 and 9, the semiconductor package 10 may further include a conductive adhesive film 420 between the conductive connection part 300 and the heat slug 500. The conductive adhesive film 420 may be, for example, a conductive tape, conductive paste, solder or combinations thereof. The conductive connection part 300 and the heat slug 500 may be connected without using the conductive adhesive film 420. That is, the conductive connection part 300 and the heat slug 500 are wetted to each other, to form a connection part. However, a top surface of the conductive connection part is at the same height as a top surface of a molding member and the heat slug 500 is formed of a planar panel, it may be difficult to achieve wetting of the conductive connection part 300 and the heat slug 500 to form a connection part. Therefore, in order to facilitate connection between the conductive connection part 300 and the heat slug 500, the conductive adhesive film 420 may be used. Since the conductive connection part 300 is electrically connected to the heat slug 500, the conductive adhesive film 420 is made of an electrically conducting material.

When the conductive adhesive film 420 is formed of, for example, a conductive tape or conductive paste, it is formed on an exposed portion of the conductive connection part 300 or a portion of the heat slug 500 located to correspond to the conductive connection part 300. Thereafter, the conductive adhesive film 420 connects the heat slug 500 to the conductive connection part 300. When the conductive adhesive film 420 is formed of, for example, a solder, it is formed on an exposed portion of the conductive connection part 300 or the heat slug 500 located to correspond to the conductive connection part 300. Thereafter, the heat slug 500 and the conductive connection part 300 are made to face each other, followed by performing heat treatment, thereby electrically connecting the heat slug 500 and the conductive connection part 300.

Referring to FIG. 9, a space may be created between the heat slug 500 and the semiconductor chip 200. The space between the heat slug 500 and the semiconductor chip 200 is created due to an existence of the conductive adhesive film 420. The space between the heat slug 500 and the semiconductor chip 200 may be smaller than a thickness of the conductive adhesive film 420.

A semiconductor package according to an embodiment of the present general inventive concept will now be described with reference to FIGS. 10 to 13. The semiconductor package of FIGS. 10 through 13 is substantially the same as the semiconductor package 10 illustrated in FIGS. 1 to 7, except that a top surface of a semiconductor chip is not exposed, and thus the same portions will not be repeatedly described or briefly described.

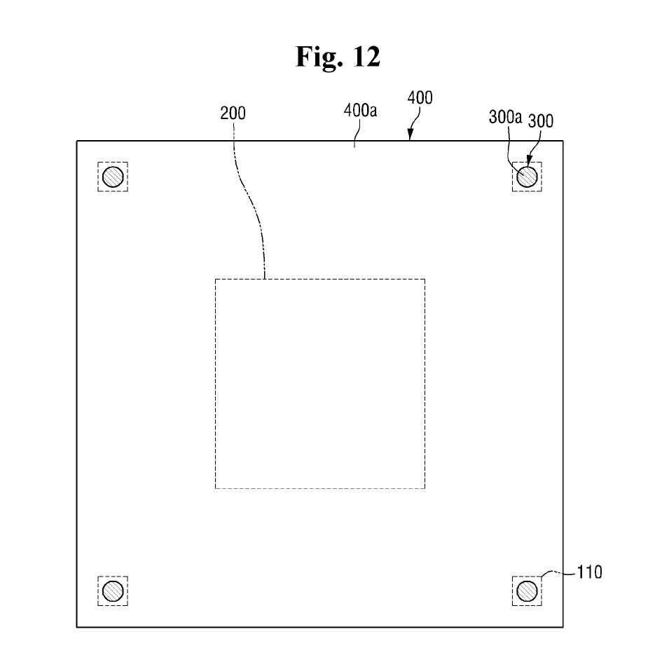

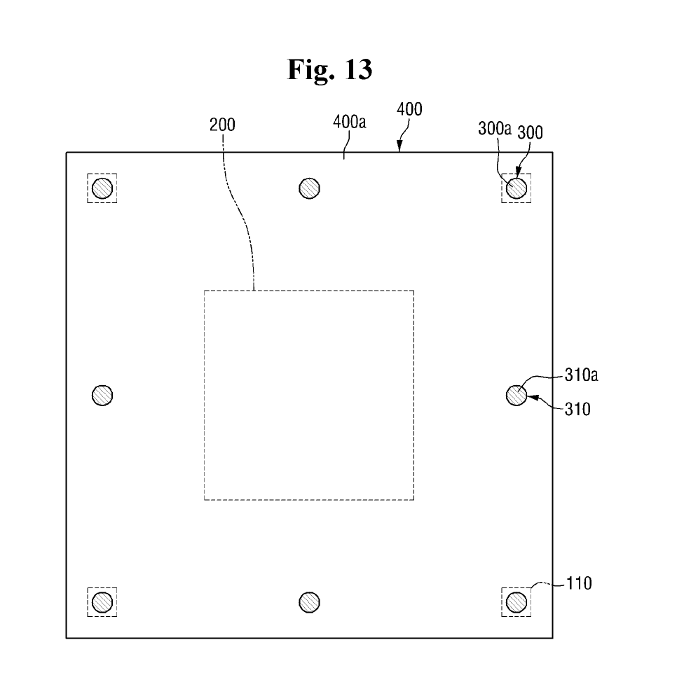

FIG. 10 is a cross-sectional view illustrating a semiconductor package according to an embodiment of the present general inventive concept, FIG. 11 is a cross-sectional view illustrating a modified example of the semiconductor package of FIG. 10, and FIGS. 12 and 13 are plan views illustrating a portion of the semiconductor of FIG. 10 when a heat slug is excluded.

Referring to FIGS. 1 and 10, in the semiconductor package 10 according to an embodiment of the present general inventive concept, a portion of a molding member 400 is disposed between the top surface 200a of the semiconductor chip 200 and a heat slug 500. The semiconductor chip 200 is connected to the heat slug 500 by means of the molding member 400. The semiconductor chip 200 may be electrically connected to a substrate 100 by means of a solder ball 200s. The semiconductor chip 200 may be formed of a flip chip type, for example, and the solder ball 200s may be formed on a surface where semiconductor device circuits are formed. Alternatively, the solder ball 200s may be connected to a silicon through-electrode penetrating the semiconductor chip 200. When the molding member 400 positioned on the top surface 200a of the semiconductor chip 200 has a thickness t4 and the semiconductor chip 200 including the solder ball 200s has a thickness t3, the conductive connection part 300 has a thickness t equal to a sum of the thickness t3 of the semiconductor chip 200 and the thickness t4 of the molding member 400 positioned on the top surface 200a of the semiconductor chip 200. In addition, a distance ranging from a mounting surface 100a of the substrate 100 to a top surface of the conductive connection part 300, that is, a height of the conductive connection part 300, is equal to the thickness t4 of the molding member 400. Here, the term “equal height” may be used to mean two or more heights compared are completely equal to each other and to encompass a height difference generated due to a processing margin. The conductive connection part 300 and the heat slug 500 may be wetted to then be connected to each other.

Referring to FIG. 11, the semiconductor chip 200 is electrically connected to the substrate 100 through a wiring 200w. In the semiconductor package described with reference to FIGS. 1 to 7, when the top surface 200a of the semiconductor chip 200 is exposed to the outside of the molding member 400, the wiring 200w may be damaged due to the heat slug 500. However, when the molding member 400 is disposed on the top surface 200a of the semiconductor chip 200, the wiring 200w may be protected by the molding member 400. Therefore, the substrate 100 and the semiconductor chip 200 may be connected to each other using the wiring 200w. A height of a top portion of the wiring 200w may be smaller than the height of the conductive connection part 300.

Referring to FIGS. 12 and 13, the semiconductor chip 200 is covered by the molding member 400. The semiconductor chip 200 is not exposed within the top surface 400a of the molding member 400. The top surface 300a of the conductive connection part 300 is exposed to the outside of the molding member 400. In FIG. 13, the top surface 310a of supporters and the top surface 400a of the molding member 400 are exposed on the top surface 400a of the molding member 400. The conductive connection parts 300 are disposed on all ground pads 110 and the supporters 310 are disposed between each of the conductive connection parts 300. Here, an exemplary positional relationship between the conductive connection parts 300 and the supporters 310 is provided only for illustration, but aspects of the present invention are not limited thereto.

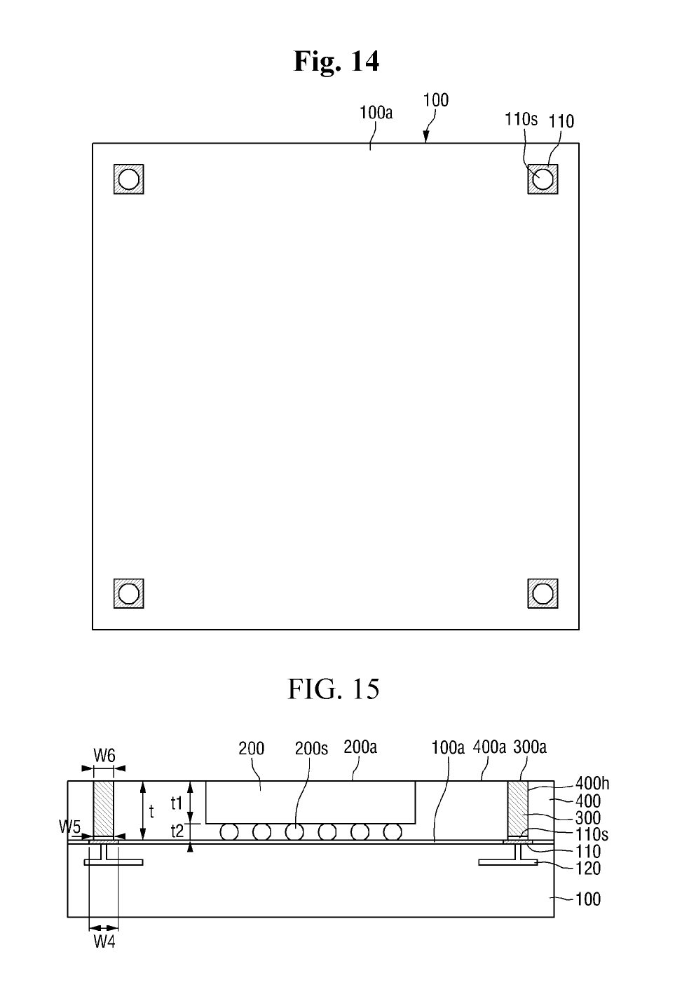

A semiconductor package according to an embodiment of the present general inventive concept will now be described with reference to FIGS. 14 and 15. The semiconductor package of FIGS. 14 and 15 is substantially the same as the semiconductor package 10 illustrated in FIGS. 1 to 7, except for a configuration of a conductive connection part, and thus the same portions will not be repeatedly described or briefly described.

FIGS. 14 and 15 are cross-sectional views illustrating a semiconductor package according to an embodiment of the present general inventive concept.

Referring to FIGS. 1 and 14, the substrate 100 includes the mounting surface 100a on which a plurality of ground pads 110 are formed. Pre-solders 110s are formed on the plurality of ground pads 110. Although FIG. 14 shows that each of the pre-solders 110s partially covers the ground pads 110, which is provided only for convenient explanation, the present general inventive concept is not limited thereto. The mounting surface 100a and semiconductor chip 200 are wrapped using the molding member 400. Then, in order to form conductive connection parts, holes may be formed in the molding member 400 so as to expose the ground pads 110 therethrough. Here, the pre-solders 110s may protect the ground pads 110. In addition, the pre-solders 110s allow the conductive connection parts 300 to well adhere to the ground pads 110 when the conductive connection parts 300 are connected to the substrate 100.

Referring to FIG. 15, side surfaces of the conductive connection part 300 is wrapped by the molding member 400. For example, the conductive connection part 300 may have a cylindrical shape, a polygonal shape or a truncated cone shape, but aspects of the present invention are not limited thereto. The conductive connection parts 300 may be connected to the pre-solders 110s positioned on the ground pads 110. When the conductive connection part 300 is shaped of a truncated cone, a width W5 of a portion adjacent to the ground pad 110 is smaller than a width W6 of the top surface 300a of the conductive connection part 300. The conductive connection parts 300 may be formed by forming the holes in the molding member 400 using, for example, laser drilling. In view of the laser drilling, the width W5 of a portion adjacent to the ground pad 110 should be smaller than or equal to the width W6 of the top surface 300a of the conductive connection part 300 exposed to the outside. A width W4 of the ground pad 110 may be wider than one of the width W5 and the width W6.

A semiconductor package according to an embodiment of the present general inventive concept will now be described with reference to FIGS. 16A to 16B. The semiconductor package of FIGS. 16A and 16B is substantially the same as the semiconductor package 10 illustrated in FIGS. 1 to 7, except for a plurality of semiconductor chips provided in the semiconductor packages, and thus the same portions will not be repeatedly described or briefly described.

FIGS. 16A and 16B are cross-sectional views illustrating a semiconductor package 10 according to an embodiment of the present general inventive concept.

Referring to FIGS. 1 and 16A, the semiconductor package 10 includes the substrate 100, an upper semiconductor chip 200t, a lower semiconductor chip 200tb, the conductive connection part 300, the molding member 400, and the heat slug 500. The substrate 100 includes the mounting surface 100a on which a plurality of ground pads 110 are formed. The lower semiconductor chip 200b, disposed on the mounting surface 100a, is electrically connected to the substrate 100. The upper semiconductor chip 200t, disposed on the lower semiconductor chip 200b, is electrically connected to the lower semiconductor chip 200b. The conductive connection part 300 is connected to at least one of the plurality of ground pads 110 formed in the mounting surface 100a. The conductive connection part 300 may be, for example, a solder ball. The molding member 400 wraps the mounting surface 100a, the conductive connection part 300, the lower semiconductor chip 200b and the upper semiconductor chip 200t and exposes a top surface (300a of FIG. 1) of the conductive connection part 300. The heat slug 500 is disposed on the molding member 400 and is connected to the top surface 300a of the conductive connection part 300.

The illustrated embodiment is described using two semiconductor chips, but aspects of the present invention are not limited thereto. The semiconductor package may be configured by a number of semiconductor chips stacked. The upper semiconductor chip 200t or the lower semiconductor chip 200b may be, for example, a memory chip or a logic chip. For example, the upper semiconductor chip 200t and the lower semiconductor chip 200b may be semiconductor chips of the same kind. The substrate 100, the upper semiconductor chip 200t may be electrically connected to the lower semiconductor chip 200b by a solder ball. Each of the upper semiconductor chip 200t and the lower semiconductor chip 200b may be formed of a flip chip type, for example, and the solder ball 200s may be formed on a surface where semiconductor device circuits are formed. Alternatively, the solder ball 200s may be connected to a silicon through-electrode penetrating the upper semiconductor chip 200t and the lower semiconductor chip 200b. Alternatively, one of the upper semiconductor chip 200t and the lower semiconductor chip 200b is a flip chip and the other is a chip using a silicon through-electrode.

The semiconductor package 10 according to an embodiment of the present general inventive concept may further include a supporter (310 of FIG. 6B). The supporter 310 may be wrapped by the molding member 400 and disposed on a position not overlapping positions of the ground pads 110, to be connected to a mounting surface (100a of FIG. 6B) of the substrate 100. The supporter may connect the mounting surface 100a of the substrate 100 to the heat slug 500. Referring to FIG. 6A, a top surface of the supporter 310 is exposed from the top surface 400a of the molding member 400 without being covered by the molding member 400. The supporter 310 may be wrapped by the molding member 400 and connected to the mounting surface 100a of the substrate while not overlapping with the ground pad 110.

Referring to FIG. 16B, the lower semiconductor chip 200b is electrically connected to the substrate 100 by wiring. The upper semiconductor chip 200t is electrically connected to the lower semiconductor chip 200b by a solder ball. When the upper semiconductor chip 200t is exposed to the outside of the molding member 400, the wiring may be damaged due to the heat slug 500. Accordingly, it may be difficult to connect the upper semiconductor chip 200t to the substrate 100 or the lower semiconductor chip 200b using the wiring 200w. However, as illustrated in FIG. 11, when the molding member 400 is disposed on the upper semiconductor chip 200t, the wiring 200w may be protected by the molding member 400. Accordingly, the upper semiconductor chip 200t may be electrically connected to the substrate 100 or the lower semiconductor chip 200b using the wiring.

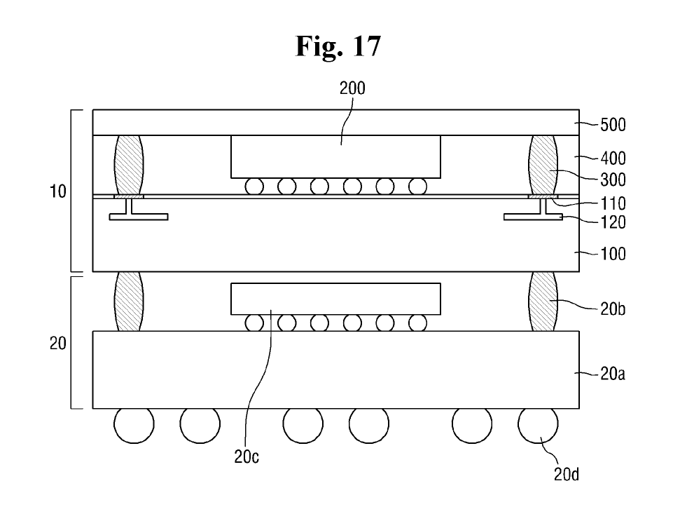

A package-on-package structure including the semiconductor package according to an embodiment of the present general inventive concept will now be described with reference to FIG. 17.

FIG. 17 illustrates a package-on-package structure using one or more semiconductor packages according to an embodiment of the present general inventive concept.

Referring to FIG. 17, the package-on-package structure includes a first semiconductor package 10 and a second semiconductor package 20. In the first semiconductor package 10, top surfaces of conductive connection parts 300 are exposed from the molding member 400. The conductive connection parts 300 electrically connect the heat slug 500 to the ground pads 110. The heat slug 500, the conductive connection parts 300 and the ground pads 110 are electrically connected. In the second semiconductor package 20, a semiconductor chip 20c is disposed on a substrate 20a of the second semiconductor package 20 to then be electrically connected. The first semiconductor package 10 and the second semiconductor package 20 are electrically connected by a package connection part 20b. At least one external terminal 20d of the second semiconductor package 20, such as a solder ball, is attached to a bottom of the substrate 20a. The external terminal 20d of the second semiconductor package 20 may electrically connect an external device to a package-on-package.

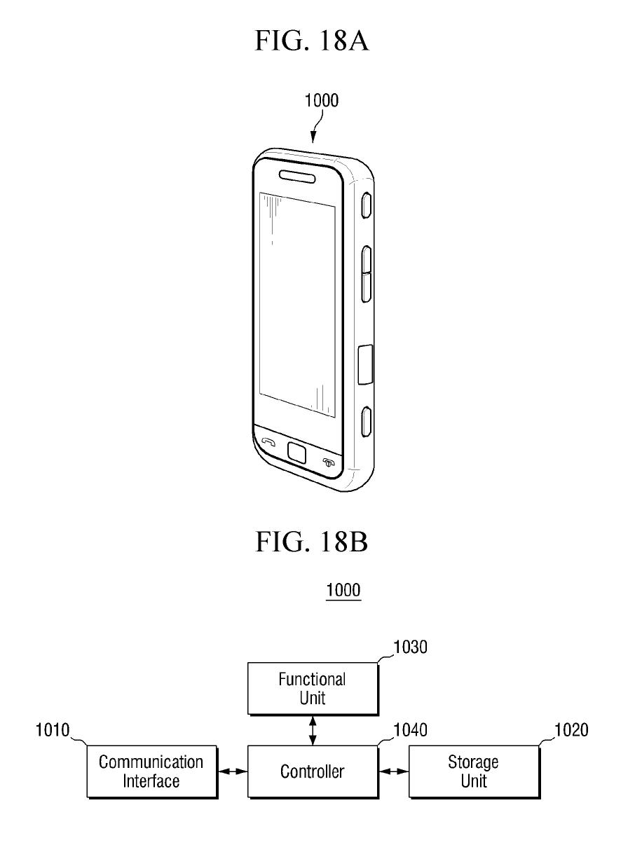

FIGS. 18a and 18B are views illustrating an electronic device 1000 having at least one semiconductor package according to an embodiment of the present general inventive concept.

Referring to FIGS. 18A and 18B, the electronic device may include a communication interface 1010 to communicate with an external system to receive data or transmit data using wires or wireless communications method, a storage unit 1020 to store data, a functional unit 1030 including a display and/or input components, such as a touch panel, and/or an audio component to perform functions of the electronic device 1000 using the data received from the external system or data stored in the storage unit 1020, and a controller 1040 to control the communication interface 1010, the storage unit 1020, and the functional unit 1030 to perform the functions of the electronic device 1000. The semiconductor package of FIGS. 1 through 17 may be used as the storage unit 1020 of the electronic device 1000. Since the semiconductor package according to the embodiment has good thermal and electrical reliability, operating reliability of the electronic device 1000 can be ensured by using the semiconductor package. The electronic device 1000 is not limited to a cellular phone illustrated in FIG. 8A, and may include various kinds of electronic devices, such as a mobile electronic device, a tablet computer apparatus, a notebook computer, a portable multimedia player (PMP), an MP3 player, a camcorder, a memory stick, or a memory card.

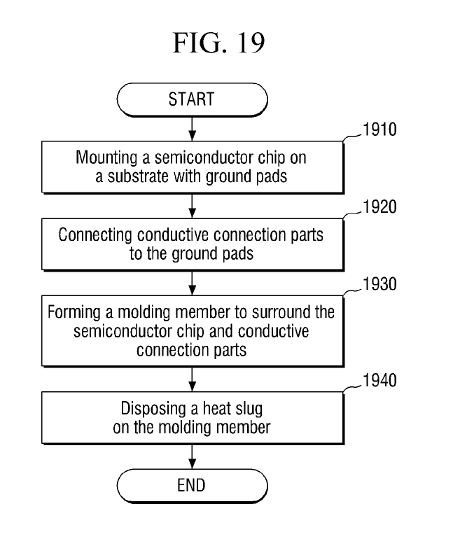

FIG. 19 is a flowchart illustrating a manufacturing method of the semiconductor package according to an embodiment of the present general inventive concept. The semiconductor package is manufactured in various manners.

The method of manufacturing the semiconductor package according to an embodiment of the present general inventive concept will be described with reference to FIGS. 1 to 3. Referring to FIGS. 1 through 3 and 19, the semiconductor chip 200 is mounted on the substrate 100, for example, the mounting surface 100a having the plurality of ground pads 110 formed thereon at operation 1910. Thereafter, conductive connection parts 300, e.g., solder balls, are connected to the ground pads 110 at operation 1920. The molding member 400is formed to wrap the mounting surface 100a, the conductive connection parts 300 and the semiconductor chip 200 at operation 1930. When the top surface 300a of the conductive connection part 300 and the top surface 200a of the semiconductor chip 200 may have been buried by the molding member 400, the molding member 400 is grinded until the top surface 300a of the conductive connection part 300 is exposed. The heat slug 500 is disposed on the top surface 400a of the grinded molding member 400 at operation 1940. The heat slug 500 and the conductive connection parts 300 may be wetted to each other through heat treatment, for example. As the result, a connection part is formed between the heat slug 500 and the conductive connection part 300, thereby electrically connecting the ground pads 110, the heat slug 500 and the conductive connection parts 300.

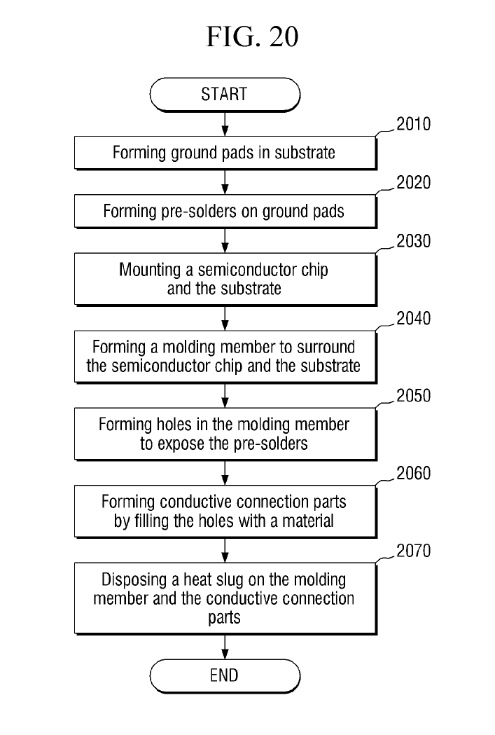

FIG. 20 is a flowchart illustrating a method of manufacturing the semiconductor package according to an embodiment of the present general inventive concept, and the method of FIG. 20 will be described with reference to FIGS. 14 and 15. Referring to FIGS. 14, 15 and 20, the plurality of ground pads 110 are formed on the mounting surface 100a at operation 2010. The pre-solders 110s are formed on the ground pads 110 at operation 2020. The semiconductor chip 200 is mounted on the substrate 100 at operation 2030. The molding member 400, which wraps the mounting surface 100a and the semiconductor chip 200, is then formed at operation 2040. Thereafter, holes are formed at locations corresponding to the ground pads 110 on the top surface 400a of the molding member 400 at operation 2050. A process of forming the holes may be performed by, for example, laser drilling. The pre-solders 110s are exposed by the holes formed in the molding member 400 at operation 2050. The holes formed in the molding member 400 are filled with, for example, a solder material, thereby forming the conductive connection parts 300 at operation 2060. Then, the heat slug 500 is disposed on the conductive connection parts 300 and the top surface 400a of the molding member 400 at operation 2070. The heat slug 500 and the conductive connection parts 300 are connected by forming connection parts between the heat slug 500 and the conductive connection parts 300 through the heat treatment. As the result, the connection parts are formed between the heat slug 500 and the conductive connection parts 300, thereby electrically connecting the ground pads 110, the heat slug 500 and the conductive connection parts 300.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A semiconductor package comprising:
a substrate including a mounting surface having a plurality of ground pads;
a semiconductor chip disposed on the mounting surface;
a conductive connection part connected to at least one of the plurality of ground pads and having a greater width at a center than at an end;
a molding member exposing a top surface of the conductive connection part while wrapping the mounting surface, the conductive connection part and the semiconductor chip; and
a heat transferring unit disposed on the molding member and connected to the top surface of the conductive connection part.

2. The semiconductor package of claim 1, wherein the top surface of the semiconductor is exposed.

3. The semiconductor package of claim 1, further comprising:
a supporter wrapped by the molding member and connected to the mounting surface while not overlapping with the ground pad,
wherein a top surface of the supporter is exposed.

4. The semiconductor package of claim 1, wherein:
the ground pad is formed around a corner of the mounting surface; and
the conductive connection part is disposed on the ground pad.

5. The semiconductor package of claim 1, wherein the conductive connection part is a solder ball and a side surface of the conductive connection part directly contacts the molding member.

6. The semiconductor package of claim 1, wherein:
the semiconductor chip further includes a solder ball connected to the substrate; and
a sum of a height of the solder ball and a thickness of the semiconductor chip is equal to a height of the conductive connection part.

7. The semiconductor package of claim 1, further comprising:
an adhesive film formed on a top surface of the molding member not overlapping with the semiconductor chip and the conductive connection part,
wherein the adhesive film connects the heat slug with the top surface of the molding member.

8. The semiconductor package of claim 1, wherein:
the heat transferring unit comprises a heat slug;
the heat slug has a center part and an edge part wrapping the center part; and
the edge part includes a pattern formed at a location corresponding to the top surface of the conductive connection part to expose the center part.

9. (canceled)

10. The semiconductor package of claim 1, further comprising:
a conductive adhesive film between the top surface of the conductive connection part and the heat transferring unit .

11. The semiconductor package of claim 10, wherein the conductive adhesive film is one of a conductive tape, conductive paste and solder.

12. The semiconductor package of claim 1, wherein a portion of the molding member is disposed between the top surface of the semiconductor chip and the heat slug, and a height ranging from the mounting surface to the top surface of the conductive connection part is equal to a thickness of the molding member.

13. A semiconductor package comprising:
a substrate including a mounting surface having a plurality of ground pads;
a lower semiconductor chip disposed on the mounting surface;
an upper semiconductor chip disposed on the lower semiconductor chip;
a conductive connection part connected to at least one of the plurality of ground pads;
a molding member exposing a top surface of the solder ball while wrapping the mounting surface, the solder ball, the upper semiconductor chip and the lower semiconductor chip; and
a heat transferring unit disposed on the molding member and connected to the top surface of the solder ball.

14. he semiconductor package of claim 13, further comprising:
a supporter wrapped by the molding member and connected to the mounting surface while not overlapping with the ground pad,
wherein a top surface of the supporter is exposed.

15. The semiconductor package of claim 13, wherein:
the lower semiconductor chip is electrically connected to the substrate by a wiring; and
the top surface of the upper semiconductor chip is exposed.

16. The semiconductor package of claim 13, wherein the conductive connecting part comprises a solder ball formed on the corresponding ground pad, and the heat transferring unit comprises a heat slug.

17. A semiconductor package comprising:
a substrate formed with one or more ground pads at a first position of the substrate;
a semiconductor chip disposed on the substrate at a second position of the substrate;
a conductive connection part formed on the corresponding ground pad and having a width variable according to a distance from the corresponding ground pad;
a molding member formed between the semiconductor chip and the conductive connection part; and
a heat transferring unit connected to the conductive connection part and disposed to cover the molding member and at least a portion of the semiconductor chip.

18. (canceled)

19. The semiconductor package of claim 17, wherein the conductive connection part is spaced apart from the semiconductor by a distance longer than the width of the conductive connection part.

20. The semiconductor package of claim 17, wherein:
the conductive connection part has a bottom area;
the ground pad has a surface area; and
the surface area is larger than the bottom area.

21. (canceled)

22. The semiconductor package of claim 17, further comprising:
a film disposed beneath the heat transferring unit to maintain a distance from the substrate.

23. The semiconductor package of claim 17, further comprising:
a second semiconductor chip disposed between the semiconductor chip and the heat transferring unit to be electrically connected to either one of the semiconductor chip and the substrate.

24. (canceled)
